(19) United States
(12) Patent Application Publication
(10) Pub. No.: US 2026/0134933 A1
(43) Pub. Date: May 14, 2026

(54) DYNAMIC SELECT GATE SCAN MANAGEMENT

(71) Applicant: Micron Technology, Inc., Boise, ID (US)

(72) Inventors: Yee Yang Tay, Singapore (SG); Zixiang Loh, San Jose, CA (US)

(21) Appl. No.: 19/367,418

(22) Filed: Oct. 23, 2025

Related U.S. Application Data
(60) Provisional application No. 63/719,016, filed on Nov. 11, 2024.

(51) Int. Cl. G11C 16/34; G11C 16/32; G11C 29/02

(52) U.S. Cl. CPC G11C 16/3495; G11C 16/32; G11C 29/022

(57) ABSTRACT

Methods, systems, and devices for dynamic select gate scan management are described. For example, a memory system may perform a first evaluation of selection transistors (e.g., string selection transistors in a 3D NAND array), determine a result of operating the selection transistors based on performing the first evaluation, and perform a second evaluation of the selection transistors based on an access interval that is determined as a function of the result associated with the first evaluation. The result of the evaluation may indicate a quantity of selection transistors with a channel conductivity above a threshold conductivity when applying a voltage to gates of the selection transistors, and larger results (e.g., larger quantities of failed selection transistors) may be mapped to shorter access intervals (e.g., in accordance with an inverse relationship, to increase evaluation frequency as a quantity of degraded selection transistors increases).

### CROSS REFERENCE

The present Application for Patent claims priority to U.S. Patent Application No. 63/719,016 by Tay et al., entitled “DYNAMIC SELECT GATE SCAN MANAGEMENT,” filed Nov. 11, 2024, which is assigned to the assignee hereof, and which is expressly incorporated by reference in its entirety herein.

### TECHNICAL FIELD

The following relates to one or more systems for memory, including dynamic select gate scan management.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a memory system that supports dynamic select gate scan management in accordance with examples as disclosed herein.

FIG. 2 shows an example of a memory architecture that supports dynamic select gate scan management in accordance with examples as disclosed herein.

FIGS. 3A and 3B show examples of a distribution diagram and an access interval table that support dynamic select gate scan management in accordance with examples as disclosed herein.

FIG. 4 shows an example of a method that supports dynamic select gate scan management in accordance with examples as disclosed herein.

FIG. 5 shows a block diagram of a memory system that supports dynamic select gate scan management in accordance with examples as disclosed herein.

FIG. 6 shows a flowchart illustrating a method or methods that support dynamic select gate scan management in accordance with examples as disclosed herein.

### DETAILED DESCRIPTION

Some memory systems may perform periodic evaluations (e.g., scans) on one or more selection transistors (e.g., select gates, select gate source (SGS) transistors, select gate drain (SGD) transistors) of a memory array. For example, one or more selection transistors may allow access (e.g., for reading, for writing, for erasing) to a string of non-volatile memory cells (e.g., three dimensional (3D) NOT AND (NAND) memory cells). In some cases, such evaluations may determine whether selection transistors have degraded. For example, a degraded selection transistor may allow current to pass through a channel of the degraded selection transistors despite a voltage intended to deactivate the selection transistor (e.g., impede current flow through the channel) being applied to a gate of the selection transistor. In some examples, periodic selection transistor evaluations may add to a latency and power draw associated with operations of the memory system. In some cases, an access interval (e.g., a period) associated with performing selection transistor evaluations may be fixed (e.g., after performing an initial evaluation), which may cause the evaluations to occur too frequently (e.g., increasing latency while the evaluations may not detect degradation of selection transistors) or too infrequently (e.g., allowing errors to occur in the memory system that are caused by degraded selection transistors that are not detected).

In accordance with examples as disclosed herein, an access interval for performing evaluations of selection transistors may be dynamically determined as a function of a result of an evaluation of the selection transistors. For example, a memory system may perform a first evaluation of selection transistors, determine a result of operating the selection transistors based on performing the first evaluation, and perform a second evaluation of the selection transistors based on an access interval that is determined based on the result associated with the first evaluation. In some cases, the evaluation may include applying a voltage to a gate of the selection transistors and evaluating a conductivity of a channel (e.g., a channel conductivity) of each of the selection transistors (e.g., whether the channel conductivity is above a threshold, whether a resistance of the channel is below a threshold, whether the channel is activated, whether current flows through the channel). The result associated with the evaluation may indicate a quantity of selection transistors with an associated channel conductivity above a threshold conductivity when applying the voltage to the gate (e.g., degraded selection transistors, failed transistors, activated selection transistors). In some cases, to determine the access interval, the memory system may use a table that maps one or more ranges of results to one or more access intervals, where larger results (e.g., larger quantities of failed selection transistors) may be mapped to shorter access intervals (e.g., in accordance with an inverse relationship, to increase evaluation frequency as a quantity of degraded selection transistors increases). In some cases, an access intervals may correspond to a quantity of erase cycles (e.g., program erase cycles (PECs)), a quantity of read operations (e.g., a read count), or a combination thereof, associated with the evaluated selection transistors (e.g., to a portion of a memory array that includes the evaluated selection transistors). The ranges of results may be referred to as bins, and the table may be stored at a memory system (e.g., at a memory device, at a memory system controller), at a host system, or both. Additionally, different portions of a memory array (e.g., each of a set of one or more blocks) may be associated with a respective dynamic access interval, such that the different portions may be associated with different dynamic access intervals based on different evaluation results. Thus, a memory system may perform selection transistor evaluations at dynamic access intervals, which may reduce latency at the memory system when the selection transistors are relatively less degraded and may increase reliability of the memory system when the selection transistors are relatively more degraded.

In addition to applicability in memory systems as described herein, techniques for dynamic select gate scan management may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving understanding of device degradation, which may improve performance and longevity and reduce operational margins, among other benefits.

Features of the disclosure are illustrated and described in the context of systems, devices, and circuits. Features of the disclosure are further illustrated and described in the context of distribution diagrams, access interval tables, and flowcharts.

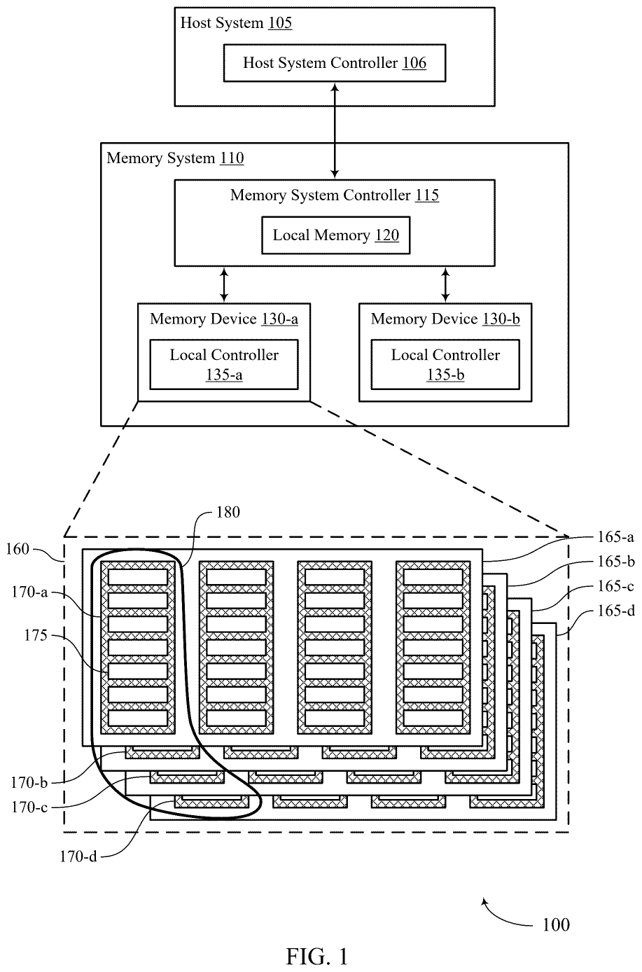

FIG. 1 shows an example of a system 100 that supports dynamic select gate scan management in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0 ” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In accordance with examples as disclosed herein, an access interval for performing evaluations of selection transistors of a memory system 110 (e.g., of one or more memory devices 130, of one or more blocks 170) may be dynamically determined as a function of a result of an evaluation of the selection transistors. For example, a memory system 110 may perform a first evaluation of selection transistors, determine a result of operating the selection transistors based on performing the first evaluation, and perform a second evaluation of the selection transistors based on an access interval that is determined based on the result associated with the first evaluation. Thus, a memory system 110 may perform selection transistor evaluations at dynamic access intervals, which may reduce latency at the memory system 110 when the selection transistors are relatively less degraded and may increase reliability of the memory system 110 when the selection transistors are relatively more degraded.

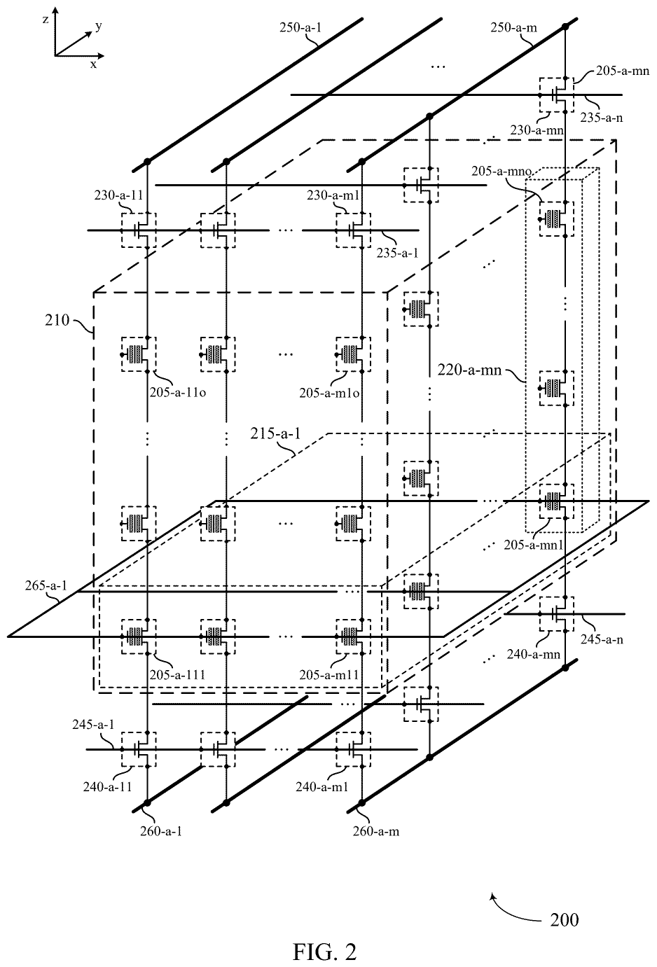

FIG. 2 shows an example of a memory architecture 200 that supports dynamic select gate scan management in accordance with examples as disclosed herein. The memory architecture 200 may be an example of a portion of a memory system 110, such as a portion of a memory device 130. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction (e.g., a first direction over a substrate), a y-direction (e.g., a second direction over the substrate), and a z-direction (e.g., a direction from the substrate) of the illustrated coordinate system.

The memory architecture 200 includes a three-dimensional array of memory cells 205, which may be examples of memory cells of a die 160 (e.g., transistors, NAND memory cells). In some examples, the memory cells 205 may be connected in a 3D NAND configuration. For example, the memory cells 205 may be included in a block 210, which may be an example of a block 170. A block 210 may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory system 110 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215, each of which may be an example of a page 175) along the z-direction, including a page 215-a-1 associated with memory cells 205-a-111 through 205-a-mn1. In some examples, each page 215 may be associated with the same word line 265, (e.g., a word line), which may be coupled with a control gate of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor, a continuous semiconductor channel material) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, each string 220 of a block 210 may be coupled with a respective transistor 230 (e.g., a string select transistor, a drain select transistor, a selection transistor) at one end of the string 220 (e.g., along the z-direction, opposite a substrate from the block 210) and a respective transistor 240 (e.g., a source select transistor, a ground select transistor, a selection transistor, between the block 210 and a substrate) at the other end of the string 220. In some examples, a drain of each transistor 230 may be coupled with a bit line 250 of a set of bit lines 250 associated with the block 210. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure of memory cells 205. In some cases, respective voltages may be applied to the word line 265 of the page 215 and the bulk of the memory cell 205 to be programmed such that a control gate of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material (e.g., a gate dielectric) of the memory cell 205 and thereby injected into the charge trapping structure of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure of the memory cell 205. In some cases, respective voltages may be applied to the word line 265 of the page 215 and the bulk of the memory cell 205 to be erased such that a control gate of the memory cell 205 is at a lower voltage than the bulk of the memory cell 205 (e.g., a positive voltage may be applied to the bulk), which may cause an electric field that pulls electrons out of the charge trapping structure and into the bulk of the memory cell 205. In some cases, a single program operation may erase all memory cells 205 in a block 210, as the memory cells 205 of the block 210 may all share a common bulk.

A memory system 110 may perform periodic evaluations (e.g., scans) to evaluate operations of transistors 230, transistors 240 or both (e.g., selection transistors, select gates), which may determine whether transistors 230 or 240 have degraded. For example, a degraded transistor 230 or a degraded transistor 240 may allow current to pass through a channel of the degraded transistor (e.g., along a string 220) despite a voltage intended to deactivate the selection transistor (e.g., impede current flow through the channel) being applied to a gate of the selection transistor (e.g., via a select line 235, via a select line 245). In some examples, periodic selection transistor evaluations may add to a latency and power draw associated with operations of a memory system 110. In some cases, an access interval (e.g., a period) associated with performing selection transistor evaluations may be fixed (e.g., after performing an initial evaluation), which may cause the evaluations to occur too frequently (e.g., increasing latency while the evaluations may not detect degradation of transistors 230 or transistors 240) or too infrequently (e.g., allowing errors to occur in a memory system 110 or memory device 130 that are caused by degraded transistors 230 or transistors 240 that are not detected).

In accordance with examples as disclosed herein, an access interval for performing evaluations of selection transistors (e.g., transistors 230, transistors 240, or both) may be dynamically determined (e.g., at a host system controller 106, at a memory system controller 115, at a local controller 135) as a function of a result of an evaluation of the selection transistors. For example, a memory system 110 (e.g., a memory device 130) may perform a first evaluation of selection transistors, determine a result of operating the selection transistors based on performing the first evaluation, and perform a second evaluation of the selection transistors based on an access interval that is determined (e.g., by a host system controller 106, by a memory system controller 115, by a local controller 135) based on the result associated with the first evaluation.

In some cases, the evaluation may include applying a voltage to a gate of the selection transistors (e.g., via select lines 235, via select lines 245) and evaluating a conductivity of a channel (e.g., a channel conductivity) of each of the selection transistors (e.g., whether the channel conductivity is above a threshold, whether a resistance of the channel is below a threshold, whether the channel is activated, whether current flows through the channel). For example, if conductivity of a selection transistor is too high for a given gate voltage (e.g., deselection voltage), non-targeted strings 220 may be inadvertently coupled with a bit line 250, a source line 260, or both, which may cause access errors (e.g., write errors, read errors). To support such evaluations, other portions of a channel along a given string may also be activated. For example, when evaluating transistor(s) 230 of a block 210 (e.g., to evaluate conductivity of a transistor 230 for a given evaluation bias applied to a select line 235), each of the word lines 265 may be biased with an activation voltage (e.g., VREAD) to activate channels along corresponding strings 220, and corresponding transistor(s) 240 (e.g., on an opposite end of a string 220) may also be biased with an activation voltage (e.g., to cause the transistor(s) 240 to have a conductive channel). In such an evaluation, a bias applied to gates of the transistor(s) 230 via a select line 235 may be different than (e.g., higher than) a voltage associated with deselecting transistors 230 during access operations, which may provide a proactive (e.g., conservative) evaluation of transistors 230 before operational failure may be experienced (e.g., to evaluate threshold voltage degradation of transistors 230 before reaching a point of access failure). Likewise, when evaluating transistor(s) 240 of a block 210 (e.g., to evaluate conductivity of a transistor 240 for a given evaluation bias applied to a select line 245), each of the word lines 265 may be biased with the activation voltage and corresponding transistor(s) 230 may also be biased with an activation voltage.

The result associated with the evaluation may indicate a quantity of selection transistors (e.g., transistors 230, transistors 240, or both) with an associated channel conductivity above a threshold conductivity when applying the voltage to the gate (e.g., degraded selection transistors, failed transistors, activated selection transistors). In some cases, to determine the access interval, the system (e.g., a host system controller 106, a memory system controller 115, a local controller 135) may use a table that maps one or more ranges of results to one or more access intervals, where larger results (e.g., larger quantities of failed selection transistors) may be mapped to shorter access intervals (e.g., in accordance with an inverse relationship, to increase evaluation frequency as a quantity of degraded selection transistors increases). In some cases, an access intervals may correspond to a quantity of erase cycles (e.g., program erase cycles (PECs)), a quantity of read operations (e.g., a read count), or a combination thereof, associated with the evaluated selection transistors (e.g., to a block 210 associated with the evaluated selection transistors). The ranges of results may be referred to as bins, and the table may be stored at a memory system 110 (e.g., at a memory device 130, at a memory system controller 115), at a host system 105, or both. Additionally, different portions of a memory array (e.g., each of a set of one or more blocks 210) may be associated with a respective dynamic access interval, such that the different portions may be associated with different dynamic access intervals based on different evaluation results. Thus, a memory system 110 may perform selection transistor evaluations at dynamic access intervals, which may reduce latency at the memory system 110 when the selection transistors are relatively less degraded and may increase reliability of the memory system 110 when the selection transistors are relatively more degraded.

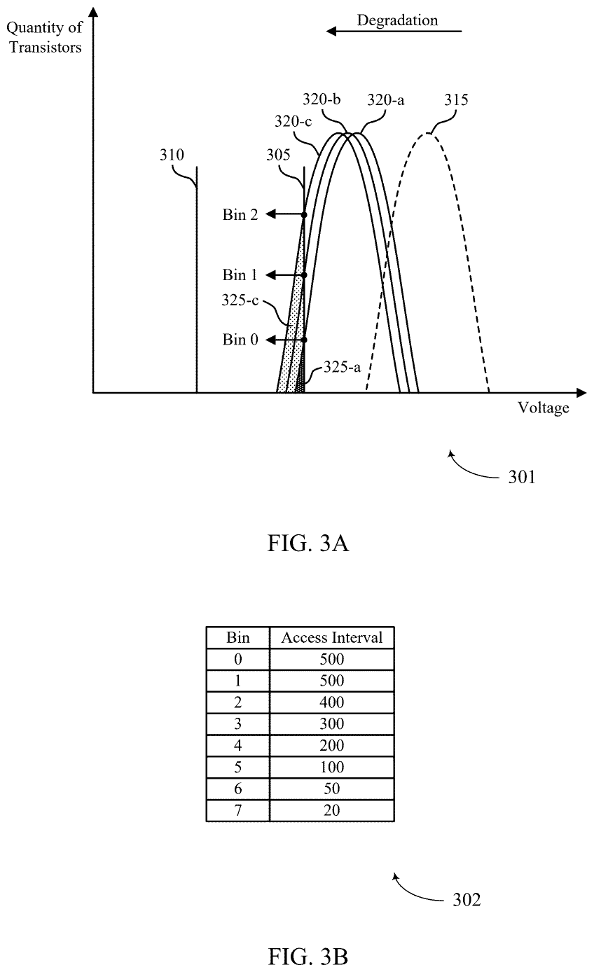

FIGS. 3A and 3B show examples of a distribution diagram 301 and an access interval table 302 that support dynamic select gate scan management in accordance with examples as disclosed herein. Aspects of the distribution diagram 301 and the access interval table 302 may implement or be implemented by aspects of a system 100 or a memory architecture 200. For example, the distribution diagram 301 may illustrate distributions 315 and 320 (e.g., distributions 320-a, 320-b, and 320-c) of threshold voltages of selection transistors (e.g., threshold voltages of transistors 230, transistors 240, or both) as well as results 325 (e.g., a result 325-a corresponding to the distribution 320-a, a result 325-c corresponding to the distribution 320-c, as an area under the distribution curve, as a quantity of selection transistors) associated with evaluation of selection transistors. The access interval table 302 may illustrate an example of bins (e.g., ranges of results associated with selection transistor evaluations) and corresponding access intervals. A memory system 110 may perform evaluations on selection transistors and determine a result 325 associated with the evaluation (e.g., based on a distribution 320 of the threshold voltages of the selection transistors), and the result 325 may be associated with a bin and an access interval (e.g., based on the access interval table 302).

In some memory systems 110, periodic evaluation of selection transistors (e.g., select gate scans) may proactively counteract degradation (e.g., threshold voltage decay) of the selection transistors, which may increase a reliability of the memory system 110 (e.g., reduce errors associated with the selection transistors). In some cases, a memory system 110 may perform periodic evaluations after threshold quantity of access operations (e.g., erase cycles, PECs, an initial threshold read count), and the threshold may depend on the type of access operations (e.g., quad-level cell (QLC) access operations, tri-level cell (TLC) access operations, single-level cell (SLC) access operations, or weighted combination thereof). Additionally, or alternatively, a memory system 110 may perform an evaluation in response to an initial power on or an initial coupling with a host system 105. In some cases, an access interval (e.g., period) at which a memory system 110 performs evaluations may be fixed, which may lead to adverse operation of the memory system 110. For example, a relatively low access interval (e.g., more-frequent evaluations, a smaller period) may increase overhead, which may increase write amplification and latency effects on the memory system 110. In some other examples, a relatively high access interval (e.g., less-frequent evaluations, a larger period) may allow for more errors caused by degraded selection transistors before an evaluation occurs (e.g., selection transistor failures may not be observed before access errors), which may reduce a reliability of the memory system 110.

In some examples, a fixed access interval may create a reliability “blind spot” during a life cycle of a memory device 130. For example, evaluations performed at a fixed access interval may not be able to capture a natural variation or acceleration in wear and degradation of a memory device 130, which may impede evaluations from detecting selection transistor failures before they cause reliability issues (e.g., access errors). A fixed access interval may also be unable to handle variations between memory devices 130 or dies 160 within a memory system 110 (e.g., device-to-device variation, die-to-die variation). For example, due to a manufacturing variability, threshold voltages for selection transistors of different memory devices 130 or dies 160 may vary, and a slope of charge gain or charge loss with respect to time for selection transistors of different memory devices 130 or dies 160 may also vary. Therefore, a fixed access interval for selection transistor evaluations may produce varying results in different memory devices 130 or dies 160, which may lead to underestimation or overestimation of degradation in some such components. Although operating in accordance with a lower fixed access interval may reduce errors regardless of variations, the evaluations may cause overhead (e.g., latency) in the memory devices 130, and decreasing the access interval (e.g., increasing a frequency of evaluations) to improve reliability may therefore increase latency and power usage at a memory system 110 (e.g., reducing performance and power margin at the memory system 110).

In an illustrative example, an initial threshold for access operations before beginning selection transistor evaluations may be 1000 access operations (e.g., for QLC access operations, or 20,000 SLC access operations). A memory system 110 may initiate a first evaluation when an access operation count exceeds the initial threshold. Once initiated, the memory system 110 may perform the evaluations at the fixed access interval. For example, the access interval may be 100 access operations (e.g., for QLC access operations, or 1000 SLC access operations). However, errors may occur more frequently than the fixed access interval can account for. For example, after 1000 access operations, the next evaluation may occur at 1100 access operations, but errors may occur in the memory system 110 due to degraded selection transistors before 1100 access operations. Additionally, or alternatively, errors may occur before the initial threshold is satisfied. Further, evaluations of selection transistors may output (e.g., provide as a result) a status flag (e.g., a pass or fail indication) associated with some or all of the selection transistors (e.g., of a block 170) which may not indicate (e.g., to a memory system controller 115) a degree of degradation of the selection transistors, impeding the memory system 110 from avoiding use of the selection transistors (e.g., the block 170, or portion thereof) if the selection transistors pass the evaluation by a small margin. Thus, a fixed access interval, an initial threshold, or both, may leave a memory system 110 vulnerable to selection transistor degradation.

Techniques described herein may allow for a dynamic access interval for selection transistor evaluations. For example, such techniques may include detecting (e.g., by a memory system controller 115, by a local controller 135, by a host system controller 106, or a combination thereof) a degradation level of selection transistors (e.g., a margin for selection transistors threshold voltages) of at least a portion of a memory device 130 (e.g., associated with one or more blocks 170). In some implementations, a memory system 110 (e.g., a memory system controller 115, a local controller 135, or combination thereof) may use such information adjust the access interval internally (e.g., as determined at the memory system controller 115, the local controller 135, or combination thereof). In some other implementations, a memory system 110 (e.g., a memory system controller 115, a local controller 135) may indicate such information to a host system 105 (e.g., a host system controller 106), such that the access interval may be adjusted by the host system 105 (e.g., by the host system controller 106).

A memory system 110 may employ one or more operations to detect a degradation level of transistors. For example, some memory systems 110 may sense a read margin for a threshold voltage of memory cells 205, and such operations may collectively be known as valley track logic. For example, operations may obtain a measure of a threshold voltage of a memory cell 205 (e.g., a lowest voltage supplied at a control gate of the memory cell 205, such as a voltage of a word line 265, at which current will flow through the memory cell 205) and may return the value of the threshold voltage for the memory cell 205. A memory system 110 may also use such operations for memory cell calibration management (e.g., not for selection transistors, such as transistors 230 and transistors 240). In accordance with examples as disclosed herein, similar operations may be performed to evaluate threshold voltages (e.g., threshold voltage degradation) of selection transistors of a memory system 110.

For example, a memory system 110 may perform operations to sense threshold voltages (e.g., a trip points, activation voltages) for selection transistors (e.g., transistors 230, transistors 240, of one or more memory devices 130, associated with one or more blocks 210). In some cases, threshold voltages of a population of selection transistors may be associated with a distribution 320, where a horizontal axis of the distribution diagram 301 may represent threshold voltages of a distribution 320, and a vertical axis of the distribution diagram 301 (“Quantity of Transistors”) may represent a quantity of selection transistors of the distribution 320 that are associated with a corresponding threshold voltage. In some cases, baseline selection transistors (e.g., nominal selection transistors, selection transistors with no degradation, new selection transistors) may be associated with threshold voltages that form a distribution 315. In such examples, distributions 320-a through 320-c may illustrate a degradation (e.g., threshold voltage decay) over time or over accumulated operations compared to the distribution 315.

In some cases, a memory system 110 may be configured with one or more voltages (e.g., applied voltages, gate voltages, select line voltages), such as the voltage 305 and the voltage 310, which may be different. For example, the voltage 310 may be a voltage that a memory system 110 (e.g., a memory device 130) uses for deselecting (e.g., deactivating, turning off) a selection transistor during an access operation (e.g., for deselecting a string 220), and the voltage 305 may be an evaluation voltage from which a result 325 (e.g., a quantity of activated selection transistors) is determined. For example, based on applying the voltage 305 to a select line (e.g., a select line 235, a select line 245), each of the selection transistors falling to the left of the voltage 305 of a given distribution 320 may be activated, and the quantity of transistors falling to the left of the voltage 305 (e.g., activated transistors, transistors having a conductivity greater than a threshold) may be counted as a result 325. A result 325 may be used to determine an access interval for subsequent evaluations (e.g., to accelerate evaluations under conditions of accelerating degradation). A difference between the voltage 305 and the voltage 310 may be a safety margin, such that a memory system 110 may detect selection transistors that are activated based on application of the voltage 305 (e.g., when the voltage 305 is applied to the gates of the selection transistors) before the selection transistors are degraded enough to be activated at the voltage 310 (e.g., during access operations, causing access errors).

To evaluate multiple selection transistors, a memory system 110 (e.g., a memory device 130) may apply the voltage 305 to a gate of each of the selection transistors, and determine a conductivity through a channel (e.g., a resistance through the channel, a voltage drop across the channel, a current across the channel, an activation of the channel) of each of the selection transistors while applying the voltage 305. For examples in which selection transistors are associated with strings 220, the related memory cells 205 may also be activated (e.g., using VREAD applied to word lines 265), and a selection transistor opposite the one being evaluated, where applicable, may also be activated (e.g., with a voltage greater than voltage 305 applied to a select line). Based on the conductivity of the channels, the memory system 110 may determine a quantity of the selection transistors that fail the evaluation at the voltage 305. For example, a failing selection transistors may have a channel conductivity that is above a threshold, a channel resistance below a threshold, or a current above a threshold, among other criteria. A result 325 associated with an evaluation may indicate the quantity of selection transistors that fail the evaluation at the voltage 305, which may increase as degradation increases (e.g., from distribution 320-a to distribution 320-c).

In some cases, each result 325 (e.g., information obtained from the trip-point or voltage 305) may be associated with a bin in the access interval table 302. For example, a bin may represent a range of quantities of failing selection transistors (e.g., a range of values for the results 325), where each bin may extend from a lower bound (e.g., a lower threshold, a minimum value, a lower result) to an upper bound (e.g., an upper threshold, a maximum value, an upper result). In some cases, the bins may form consecutive ranges such that an upper bound of a bin (e.g., bin 1) may be adjacent to a lower bound of a next bin (e.g., bin 2).

In some cases, the access interval table 302 may map (e.g., correlate) each bin with an access interval for performing selection transistor evaluations. In various examples, an access interval table 302 may be stored at a memory system 110 (e.g., a memory system controller 115, a local controller 135) or at a host system 105 (e.g., a host system controller 106) coupled with the memory system 110. In some cases, the access interval table 302 may map the bins to the access intervals (e.g., scan intervals) such that the evaluations may occur more frequently for relatively larger results 325 (e.g., higher bin numbers). For example, a result 325-c may be within a bin of a higher number (e.g., bin 2) and may correspond to a distribution 320-c that is closer to the voltage 310 (e.g., has less margin) than a distribution 320-a corresponding to a result 325-a within a bin of a lower number (e.g., bin 0). Thus, the access interval table 302 may map a smaller access interval (e.g., more frequent evaluations) the bins of higher numbers than to bins of lower numbers.

In some cases, a memory system 110 may indicate information (e.g., a result) to a controller (e.g., a memory system controller 115, a local controller 135, a host system controller 106) associated with one or more evaluations (e.g., each evaluation). For example, a component of a memory system 110 may determine and indicate a result 325 (e.g., a quantity of failing selection transistors) associated with an evaluation, a bin number based on a result 325, a proposed access interval based on the bin number from the access interval table 302, or any combination thereof. In response to the information, the respective controller may transmit an indication of the bin number (e.g., if the information from the memory system 110 includes the result 325), an access interval (e.g., if the information form the memory system 110 includes the bin number), an approval of the access interval (e.g., if the information from the memory system 110 includes the access interval), or any combination thereof, based on the access interval table 302.

The techniques described herein may be implemented to allow a system (e.g., a memory system 110, a host system 105) to dynamically manage the access interval (e.g., a periodicity, a cadence, a period) associated with selection transistor evaluations, which may improve system performance. For example, dynamic access intervals for such evaluations may reduce latency when the selection transistors are relatively less degraded, and may decrease errors related to selection transistors when they are relatively more degraded (e.g., preventing scan failure-detection misses, improving overall device reliability). Such techniques may also allow for dynamic feedback between a memory system 110 and a host system 105 to manage the access interval. Additionally, variations in memory systems 110, memory devices 130, or dies 160, and different stresses (e.g., operational, environmental) on such components, may cause varying selection transistor degradation behavior, for which a dynamic access interval (e.g., per die 160, per block 170, per memory device 130, per portion of memory) may compensate. In some cases, instead of providing pass or fail feedback, the described evaluations may determine a result 325 with a finer granularity (e.g., indicating a quantity of failing selection transistors, indicating a bin number), which may allow for configuring a dynamic access interval to reduce latency associated with evaluations while improving reliability at the memory system 110.

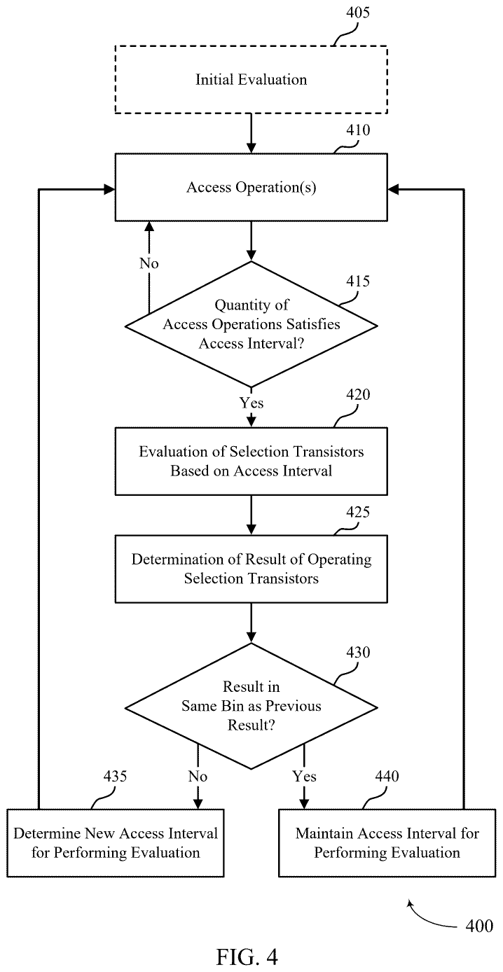

FIG. 4 shows an example of a method 400 that supports dynamic select gate scan management in accordance with examples as disclosed herein. In some cases, aspects of the method 400 may implement or be implemented by a system 100, or a memory architecture 200. For example, the method 400 may include one or more operations performed by a memory system 110 (e.g., a memory system controller 115, a memory device 130, a local controller 135), a host system 105 (e.g., a host system controller 106), or a combination thereof. In some aspects, the method 400 may illustrate an algorithm that a memory system 110, a host system 105, or both may implement to support dynamic select gate scan management. In the following description of method 400, the operations may be performed in a different order than the order shown, or other operations may be added or removed from the method 400. For example, some operations may be left out of method 400, may be performed in different orders or at different times, or other operations may be added to method 400.

In some cases, the operations of the method 400 may be performed by or on a NAND (e.g., a 3D NAND) memory system 110. For example, a NAND memory system 110 may include multiple selection transistors (e.g., transistors 230, transistors 240, or a combination thereof) each operable to couple a respective set of memory cells (e.g., memory cells 205, of a string 220, of a NAND memory array) with a respective access line (e.g., a bit line 250, a source line 260) of the memory array.

At 405, the method 400 may include performing (e.g., at the memory system 110, initiated by the memory system 110, initiated by the host system 105) an initial evaluation of the selection transistors. In some cases, the selection transistors may be the selection transistors of a block 170, of a memory device 130, or any other portion of the memory system 110. In some cases, the initial evaluation may be performed in response to completing an initial access interval (e.g., a preconfigured quantity of erase cycles (PECs), read count, or any combination thereof) associated with the selection transistors, or in response to an initial power on of a memory system 110, in response to an initial coupling of a memory system 110 with a host system 105, or any combination thereof. In some cases, the initial evaluation may be performed as described with reference to FIG. 3A and in a similar manner as described at 420. Additionally, or alternatively, a memory system 110 may set (e.g., be configured with, receive an indication of) an access interval for performing further evaluations of the selection transistors after performing the initial evaluation.

At 410, the method 400 may include performing (e.g., at the memory system 110, initiated by the memory system 110, initiated by the host system 105) one or more access operations. For example, the access operations may include read operations (e.g., where each read operation may increase a read count), write operations, erase operations, or any combination thereof (e.g., PECs). In some cases, a memory system 110 or host system 105 may count a quantity of access operations associated with the selection transistors (e.g., to a block 170 associated with the selection transistors) that occur after performing an initial evaluation (e.g., or a different previous evaluation, an immediately previous evaluation). For example, a memory system 110 or host system 105 may keep a read count, a write count, an erase count, a PEC count, or any combination thereof, associated with the access operations.

At 415, the method 400 may include determining (e.g., at the memory system, at the host system) if a quantity of access operations satisfies the access interval. As described herein, the access interval may be associated with a quantity of erase cycles (e.g., PECs) associated with the memory system 110, a quantity of read operations (e.g., a read count) associated with the memory system 110, or a combination thereof. If the quantity of access operations does not satisfy (e.g., is not equal to or greater than) the access interval (e.g., “No”), the method 400 may include continuing to perform access operations (e.g., associated with the selection transistors) at 410. Alternatively, if the quantity of access operations satisfies the access interval (e.g., “Yes”), the method may proceed to 420.

At 420, the method 400 may include performing (e.g., at the memory system 110, initiated by the memory system 110, initiated by the host system 105) an evaluation of the selection transistors based on the quantity of access operations satisfying the access interval (e.g., at 415). In some cases, performing the evaluation of the selection transistors may include applying a voltage (e.g., the voltage 305) to gates of the selection transistors (e.g., to a gate of each selection transistor) and evaluating a conductivity through channels of the selection transistors (e.g., through a channel of each selection transistor) based on applying the voltage to the gates. In some cases, evaluating the conductivity through the channels may correspond to evaluating whether current passes through the channels of the selection transistors while the voltage is applied to the gates of the selection transistors. In some cases, the voltage applied at 420 may be different than another voltage (e.g., the voltage 310) associated with deselecting a selection transistor during an access operation (e.g., of 410).

At 425, the method 400 may include determining (e.g., at the memory system 110) a result of operating the selection transistors based on performing the first evaluation. For example, the memory system 110 may apply a test voltage to first terminals of the selection transistors (e.g., via a bit line 250, via a source line 260) while the voltage is applied to the gates of the transistors, and may measure output signals (e.g., an output voltage, an output current) from second terminals of the selection transistors (e.g., via a source line 260, via a bit line 250) to determine the result of operating the selection transistors. In some cases, the result of operating the selection transistors (e.g., the result associated with the evaluation, a result 325) may indicate a quantity of the selection transistors for which an evaluated channel conductivity is above a threshold conductivity (e.g., a quantity of activated or failing selection transistors).

At 430, the method 400 may include determining (e.g., at the memory system 110, at the host system 105) if the result associated with the evaluation is within a same bin (e.g., range of results values) as a previous result (e.g., a result associated with the immediately previous evaluation). For example, if a first evaluation (e.g., an immediately previous evaluation) yields a first result that is in a first bin (e.g., bin 0, of FIG. 3B) and a next evaluation (e.g., a current evaluation) yields a second result that is not within the first bin (e.g., “No,” is within a second bin, such as bin 1 of FIG. 3B), the method 400 may proceed to 435. Alternatively, if the second result is within the first bin (e.g., “Yes”), the method 400 may proceed to 440.

At 435, the method 400 may include determining (e.g., at the memory system 110, at the host system 105) a new access interval for performing evaluations on the selection transistors. For example, the memory system 110 (e.g., if an access interval table 302 is stored at the memory system 110) may autonomously determine and set the new access interval based on the bin number of the result associated with the evaluation at 420 and the access interval table 302. Additionally, or alternatively, (e.g., if an access interval table 302 is stored at a host system 105) the memory system 110 may transmit an indication of the result (e.g., or the bin number associated with the result) to the host system 105, and the host system 105 may indicate and/or set the new access interval to/for the memory system 110. Based on the new access interval, the method 400 may return to 410 to perform access operations until a next quantity of access operations satisfies the new access interval. If the quantity of access operations satisfies the new access interval, the method 400 may (e.g., at 420) perform a second evaluation of the selection transistors based on the new access interval (e.g., that was determined as a function of the result of 425).

In some cases (e.g., as described with respect to FIG. 3B), the new access interval may be inversely related to the magnitude of the result (e.g., a quantity of errors among the multiple selection transistors). For example, as the result increases (e.g., as the quantity of failing selection transistors of the multiple failing transistors increases), the access interval may decrease (e.g., the quantity of erase cycles, the read count, or the quantity of PECs may decrease, as described with respect to FIG. 3B). Thus, the method 400 may support may iteratively decreasing the access interval as the selection transistors degrade, which may allow for low latency while the selection transistors are relatively less degraded and high reliability while the selection transistors are relatively more degraded.

At 440 (e.g., if the result from the evaluation at 420 is in the same bin as the immediately previous result), the method 400 may include maintaining the access interval for performing the evaluation. For example, the memory system 110 may autonomously maintain the access interval, may indicate a request to maintain the access interval, or may be configured to maintain the access interval (e.g., based on indicating the result, the bin number associated with the result, or both, to the host system or controller). The method 400 may return to 410 to perform access operations and eventually perform a second evaluation of the selection transistors based part on the access interval (e.g., that is determined to be maintained as a function of the result of 425).

In some cases, the selection transistors may be associated with a first portion of the memory system (e.g., a first block 170, a first die 160, a first memory device 130). In some cases, the method 400 may be performed (e.g., concurrently) for one or more other portions of the memory system 110 (e.g., one or more other blocks 170, one or more other dies 160, one or more other memory devices 130). For example, a system (e.g., a memory system 110, a host system 105, or combination thereof) may perform an evaluation of another set of selection transistors associated with a second portion of the memory system 110 (e.g., at another instance of 420), determine a second result of operating the other set of selection transistors based on performing the evaluation (e.g., at another instance of 425), and perform another evaluation of the other set of selection transistors based on a second access interval that is determined as the function of the result of operating the other set of selection transistors (e.g., at another instance of 430-440). In some cases, the second access interval associated with the second portion of the memory system 110 may be different than the access interval associated with the first portion of the memory system 110 (e.g., based on different results of operating the different sets of selection transistors).

Accordingly, a system (e.g., a memory system 110, a host system 105, or combination thereof) may dynamically control one or more access interval associated with one or more portions of a memory system 110 for performing evaluations on selection transistors of the memory system 110. Such dynamic access intervals may decrease latency, improve reliability, and improve a sustainability of the memory system 110.

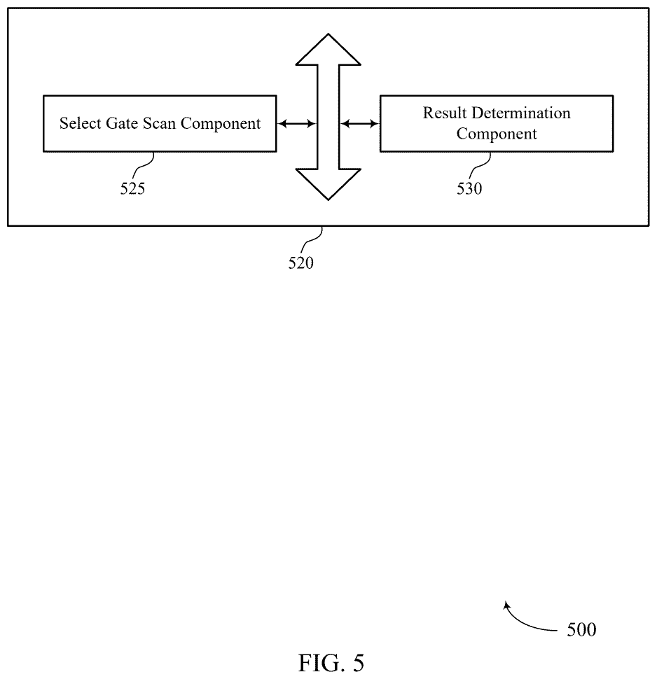

FIG. 5 shows a block diagram 500 of a memory system 520 that supports dynamic select gate scan management in accordance with examples as disclosed herein. The memory system 520 may be an example of aspects of a memory system as described with reference to FIGS. 1 through 4. The memory system 520, or various components thereof, may be an example of means for performing various aspects of dynamic select gate scan management as described herein. For example, the memory system 520 may include a select gate scan component 525 a result determination component 530, or any combination thereof (e.g., of a memory system controller 115, of one or more local controllers 135, or a combination thereof). Each of these components, or components of subcomponents thereof (e.g., one or more processors, one or more memories), may communicate, directly or indirectly, with one another (e.g., via one or more buses).

The select gate scan component 525 may be configured as or otherwise support a means for performing a first evaluation of a plurality of selection transistors of a memory array of the memory system, each of the plurality of selection transistors operable to couple a respective plurality of memory cells of the memory array with a respective access line of the memory array. The result determination component 530 may be configured as or otherwise support a means for determining a result of operating the plurality of selection transistors based at least in part on performing the first evaluation. In some examples, the select gate scan component 525 may be configured as or otherwise support a means for performing a second evaluation of the plurality of selection transistors based at least in part on an access interval of the memory array that is determined as a function of the result of operating the plurality of selection transistors.

In some examples, to support performing the first evaluation of the plurality of selection transistors, the select gate scan component 525 may be configured as or otherwise support a means for applying a voltage to gates of the plurality of selection transistors. In some examples, to support performing the first evaluation of the plurality of selection transistors, the select gate scan component 525 may be configured as or otherwise support a means for evaluating a conductivity through channels of the plurality of selection transistors based at least in part on applying the voltage to the gates.

In some examples, evaluating the conductivity through the channels corresponds to evaluating whether current passed through the channels of the plurality of selection transistors.

In some examples, the applied voltage is different than a second voltage associated with deselecting a selection transistor during an access operation.

In some examples, the result of operating the plurality of selection transistors indicates a quantity of selection transistors of the plurality of selection transistors for which the evaluated conductivity is above a threshold.

In some examples, the result of operating the plurality of selection transistors includes a quantity of failures among the plurality of selection transistors, and the determined access interval is inversely related to the quantity of errors among the plurality of selection transistors.

In some examples, the access interval is associated with a quantity of erase cycles associated with the memory array.

In some examples, the access interval is associated with a quantity of read operations associated with the memory array.

In some examples, for each of the plurality of selection transistors, the respective plurality of memory cells are aligned along a direction from a substrate of the memory array.

In some examples, for at least one of the plurality of selection transistors, the respective access line is between the respective plurality of memory cells and the substrate or, for at least one of the plurality of selection transistors, the respective access line is opposite the substrate from the respective plurality of memory cells, or a combination thereof.

In some examples, for each of the plurality of selection transistors, the respective plurality of memory cells are associated with a continuous semiconductor channel material.

In some examples, the plurality of selection transistors are associated with a first block of memory cells of the memory array, and the select gate scan component 525 may be configured as or otherwise support a means for performing a third evaluation of a plurality of second selection transistors associated with a second block of memory cells of the memory array, each of the plurality of second selection transistors operable to couple a respective plurality of second memory cells of the second block with a respective second access line of the memory array. In some examples, the plurality of selection transistors are associated with a first block of memory cells of the memory array, and the result determination component 530 may be configured as or otherwise support a means for determining a second result of operating the plurality of second selection transistors based at least in part on performing the third evaluation. In some examples, the plurality of selection transistors are associated with a first block of memory cells of the memory array, and the select gate scan component 525 may be configured as or otherwise support a means for performing a fourth evaluation of the plurality of second selection transistors based at least in part on a second access interval of the memory array that is determined as the function of the second result of operating the plurality of second selection transistors.

In some examples, the second access interval is different than the access interval based at least in part on the second result of operating the plurality of second selection transistors being different than the result of operating the plurality of selection transistors.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

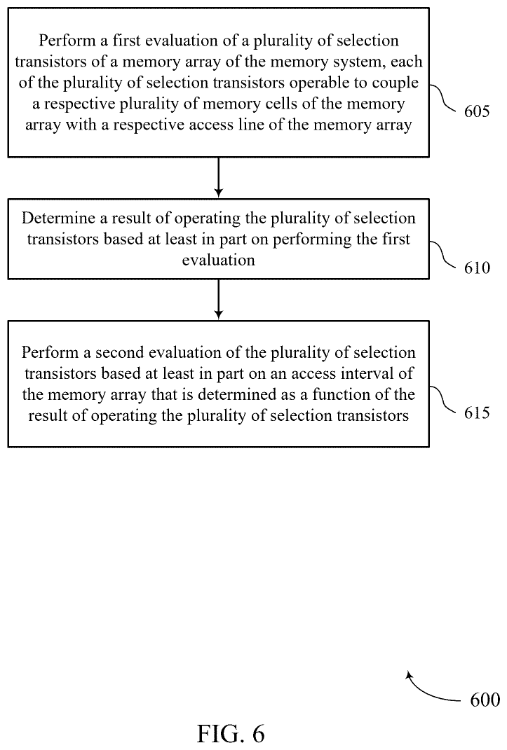

FIG. 6 shows a flowchart illustrating a method 600 that supports dynamic select gate scan management in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include performing a first evaluation of a plurality of selection transistors of a memory array of the memory system, each of the plurality of selection transistors operable to couple a respective plurality of memory cells of the memory array with a respective access line of the memory array. In some examples, aspects of the operations of 605 may be performed by a select gate scan component 525 as described with reference to FIG. 5.

At 610, the method may include determining a result of operating the plurality of selection transistors based at least in part on performing the first evaluation. In some examples, aspects of the operations of 610 may be performed by a result determination component 530 as described with reference to FIG. 5.

At 615, the method may include performing a second evaluation of the plurality of selection transistors based at least in part on an access interval of the memory array that is determined as a function of the result of operating the plurality of selection transistors. In some examples, aspects of the operations of 615 may be performed by a select gate scan component 525 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for performing a first evaluation of a plurality of selection transistors of a memory array of the memory system, each of the plurality of selection transistors operable to couple a respective plurality of memory cells of the memory array with a respective access line of the memory array; determining a result of operating the plurality of selection transistors based at least in part on performing the first evaluation; and performing a second evaluation of the plurality of selection transistors based at least in part on an access interval of the memory array that is determined as a function of the result of operating the plurality of selection transistors.
Aspect 2: The method, apparatus, or non-transitory computer-readable medium of aspect 1, where performing the first evaluation of the plurality of selection transistors includes operations, features, circuitry, logic, means, or instructions, or any combination thereof for applying a voltage to gates of the plurality of selection transistors and evaluating a conductivity through channels of the plurality of selection transistors based at least in part on applying the voltage to the gates.
Aspect 3: The method, apparatus, or non-transitory computer-readable medium of aspect 2, where evaluating the conductivity through the channels corresponds to evaluating whether current passed through the channels of the plurality of selection transistors.
Aspect 4: The method, apparatus, or non-transitory computer-readable medium of any of aspects 2 through 3, where the applied voltage is different than a second voltage associated with deselecting a selection transistor during an access operation.
Aspect 5: The method, apparatus, or non-transitory computer-readable medium of any of aspects 2 through 4, where the result of operating the plurality of selection transistors indicates a quantity of selection transistors of the plurality of selection transistors for which the evaluated conductivity is above a threshold.
Aspect 6: The method, apparatus, or non-transitory computer-readable medium of any of aspects 1 through 5, where the result of operating the plurality of selection transistors includes a quantity of failures among the plurality of selection transistors, and the determined access interval is inversely related to the quantity of errors among the plurality of selection transistors.
Aspect 7: The method, apparatus, or non-transitory computer-readable medium of any of aspects 1 through 6, where the access interval is associated with a quantity of erase cycles associated with the memory array.
Aspect 8: The method, apparatus, or non-transitory computer-readable medium of any of aspects 1 through 7, where the access interval is associated with a quantity of read operations associated with the memory array.
Aspect 9: The method, apparatus, or non-transitory computer-readable medium of any of aspects 1 through 8, where, for each of the plurality of selection transistors, the respective plurality of memory cells are aligned along a direction from a substrate of the memory array.
Aspect 10: The method, apparatus, or non-transitory computer-readable medium of aspect 9, where, for at least one of the plurality of selection transistors, the respective access line is between the respective plurality of memory cells and the substrate or, for at least one of the plurality of selection transistors, the respective access line is opposite the substrate from the respective plurality of memory cells, or a combination thereof.
Aspect 11: The method, apparatus, or non-transitory computer-readable medium of any of aspects 1 through 10, where, for each of the plurality of selection transistors, the respective plurality of memory cells are associated with a continuous semiconductor channel material.
Aspect 12: The method, apparatus, or non-transitory computer-readable medium of any of aspects 1 through 11, where the plurality of selection transistors are associated with a first block of memory cells of the memory array and the method, apparatuses, and non-transitory computer-readable medium further includes operations, features, circuitry, logic, means, or instructions, or any combination thereof for performing a third evaluation of a plurality of second selection transistors associated with a second block of memory cells of the memory array, each of the plurality of second selection transistors operable to couple a respective plurality of second memory cells of the second block with a respective second access line of the memory array; determining a second result of operating the plurality of second selection transistors based at least in part on performing the third evaluation; and performing a fourth evaluation of the plurality of second selection transistors based at least in part on a second access interval of the memory array that is determined as the function of the second result of operating the plurality of second selection transistors.

Aspect 13: The method, apparatus, or non-transitory computer-readable medium of aspect 12, where the second access interval is different than the access interval based at least in part on the second result of operating the plurality of second selection transistors being different than the result of operating the plurality of selection transistors.

It should be noted that the described methods include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
perform a first evaluation of a plurality of selection transistors of a memory array of the one or more memory devices, each of the plurality of selection transistors operable to couple a respective plurality of memory cells of the memory array with a respective access line of the memory array;
determine a result of operating the plurality of selection transistors based at least in part on performing the first evaluation; and
perform a second evaluation of the plurality of selection transistors based at least in part on an access interval of the memory array that is determined as a function of the result of operating the plurality of selection transistors.

2. The memory system of claim 1, wherein, to perform the first evaluation of the plurality of selection transistors, the processing circuitry is configured to cause the memory system to:
apply a voltage to gates of the plurality of selection transistors; and
evaluate a conductivity through channels of the plurality of selection transistors based at least in part on applying the voltage to the gates.

3. The memory system of claim 2, wherein evaluating the conductivity through the channels corresponds to evaluating whether current passed through the channels of the plurality of selection transistors.

4. The memory system of claim 2, wherein the applied voltage is different than a second voltage associated with deselecting a selection transistor during an access operation.

5. The memory system of claim 2, wherein the result of operating the plurality of selection transistors indicates a quantity of selection transistors of the plurality of selection transistors for which the evaluated conductivity is above a threshold.

6. The memory system of claim 1, wherein the result of operating the plurality of selection transistors comprises a quantity of failures among the plurality of selection transistors, and the determined access interval is inversely related to the quantity of errors among the plurality of selection transistors.

7. The memory system of claim 1, wherein the access interval is associated with a quantity of erase cycles associated with the memory array.

8. The memory system of claim 1, wherein the access interval is associated with a quantity of read operations associated with the memory array.

9. The memory system of claim 1, wherein for each of the plurality of selection transistors, the respective plurality of memory cells are aligned along a direction from a substrate of the memory array.

10. The memory system of claim 9, wherein for at least one of the plurality of selection transistors, the respective access line is between the respective plurality of memory cells and the substrate or, for at least one of the plurality of selection transistors, the respective access line is opposite the substrate from the respective plurality of memory cells, or a combination thereof.

11. The memory system of claim 1, wherein for each of the plurality of selection transistors, the respective plurality of memory cells are associated with a continuous semiconductor channel material.

12. The memory system of claim 1, wherein the plurality of selection transistors are associated with a first block of memory cells of the memory array, and the processing circuitry is further configured to cause the memory system to:
perform a third evaluation of a plurality of second selection transistors associated with a second block of memory cells of the memory array, each of the plurality of second selection transistors operable to couple a respective plurality of second memory cells of the second block with a respective second access line of the memory array;
determine a second result of operating the plurality of second selection transistors based at least in part on performing the third evaluation; and
perform a fourth evaluation of the plurality of second selection transistors based at least in part on a second access interval of the memory array that is determined as the function of the second result of operating the plurality of second selection transistors.

13. The memory system of claim 12, wherein the second access interval is different than the access interval based at least in part on the second result of operating the plurality of second selection transistors being different than the result of operating the plurality of selection transistors.

14. A method at a memory system, comprising:
performing a first evaluation of a plurality of selection transistors of a memory array of the memory system, each of the plurality of selection transistors operable to couple a respective plurality of memory cells of the memory array with a respective access line of the memory array;
determining a result of operating the plurality of selection transistors based at least in part on performing the first evaluation; and
performing a second evaluation of the plurality of selection transistors based at least in part on an access interval of the memory array that is determined as a function of the result of operating the plurality of selection transistors.

15. The method of claim 14, wherein performing the first evaluation of the plurality of selection transistors comprises:
applying a voltage to gates of the plurality of selection transistors; and
evaluating a conductivity through channels of the plurality of selection transistors based at least in part on applying the voltage to the gates.

16. The method of claim 15, wherein evaluating the conductivity through the channels corresponds to evaluating whether current passed through the channels of the plurality of selection transistors.

17. The method of claim 15, wherein the applied voltage is different than a second voltage associated with deselecting a selection transistor during an access operation.

18. The method of claim 15, wherein the result of operating the plurality of selection transistors indicates a quantity of selection transistors of the plurality of selection transistors for which the evaluated conductivity is above a threshold.

19. The method of claim 14, wherein the result of operating the plurality of selection transistors comprises a quantity of failures among the plurality of selection transistors, and the determined access interval is inversely related to the quantity of errors among the plurality of selection transistors.

20. The method of claim 14, wherein the access interval is associated with a quantity of erase cycles associated with the memory array.

21. The method of claim 14, wherein the access interval is associated with a quantity of read operations associated with the memory array.

22. A non-transitory computer-readable medium storing code comprising instructions which, when executed by processing circuitry of a memory system, cause the memory system to:
perform a first evaluation of a plurality of selection transistors of a memory array of the memory system, each of the plurality of selection transistors operable to couple a respective plurality of memory cells of the memory array with a respective access line of the memory array;
determine a result of operating the plurality of selection transistors based at least in part on performing the first evaluation; and
perform a second evaluation of the plurality of selection transistors based at least in part on an access interval of the memory array that is determined as a function of the result of operating the plurality of selection transistors.
